(19) United States
(12) Patent Application Publication
(10) Pub. No.: US 2026/0371572 A1
(43) Pub. Date: Nov. 19, 2026

(54) SEMICONDUCTOR DEVICE INCLUDING CONTACT STRUCTURE

(71) Applicant: Samsung Electronics Co., Ltd., Suwon-si (KR)

(72) Inventors: Sungnam LYU, Suwon-si (KR); Sanghyeok YU, Suwon-si (KR); Seungjin JEONG, Suwon-si (KR)

(73) Assignee: Samsung Electronics Co., Ltd., Suwon-si (KR)

(21) Appl. No.: 19/577,671

(22) Filed: Mar. 25, 2026

(30) Foreign Application Priority Data
May 19, 2025 (KR) 10-2025-0064415

(51) Int. Cl. H10B 12/00; H10D 30/67; H10W 20/00; H10W 20/41; H10W 20/44

(52) U.S. Cl. CPC H10B 12/488; H10B 12/315; H10B 12/482; H10D 30/6728; H10D 30/6755; H10D 30/6757; H10W 20/435; H10W 20/4441; H10B 12/0335; H10B 12/05; H10W 20/045

(57) ABSTRACT

A semiconductor device including a substrate; a bit line on the substrate and extending in a first direction parallel to the substrate; a channel layer including a first vertical portion on the bit line; a first word line on one side of the first vertical portion and extending in a second direction intersecting the first direction; a gate insulating film between the first word line and the channel layer; a seed layer on the channel layer; a contact structure on the seed layer, including first grains; and a capacitor structure including a lower electrode on the contact structure. Grains from among the first grains that contact an upper surface of the seed layer have a length in a third direction that is longer than a length of the grains in the second direction, and the third direction is a vertical direction that intersects the first and second directions.

### CROSS-REFERENCE TO RELATED APPLICATION

This application claims priority to Korean Patent Application No. 10-2025-0064415, filed in the Korean Intellectual Property Office on May 19, 2025, the entire contents of which are hereby incorporated by reference.

### BACKGROUND

The present disclosure relates to semiconductor devices.

Semiconductor devices are core components used to control or amplify electrical signals in electronic devices, and various types of semiconductor devices may be manufactured. For example, a memory device may be primarily used to store and retrieve data, and a non-memory device may be used to control or amplify electrical signals. Semiconductor devices, as core elements of electronic devices, play an important role in various fields such as computers, communication equipment, and consumer electronics.

With the development of industry, performance and functional requirements for electronic devices are further increasing. Accordingly, high-performance characteristics of semiconductor devices are desired, and the integration density of semiconductor devices is increasing to meet these demands. Accordingly, a transistor having a vertical channel has been proposed to improve the integration density of a semiconductor device.

### SUMMARY

Some example embodiments of the present disclosure provide a semiconductor device with improved electrical characteristics and/or reliability.

Some example embodiments of the present disclosure provide a semiconductor device that includes a substrate; a bit line on the substrate, the bit line extending in a first direction parallel to an upper surface of the substrate; a channel layer including a first vertical portion on the bit line; a first word line on one side of the first vertical portion, the first word line extending in a second direction that intersects the first direction; a gate insulating film between the first word line and the channel layer; a seed layer on the channel layer; a contact structure on the seed layer, the contact structure including a plurality of first grains; and a capacitor structure including a lower electrode on the contact structure. Grains from among the plurality of first grains that contact an upper surface of the seed layer have a length in a third direction that is longer than a length of the grains in the second direction, and the third direction is a vertical direction that intersects each of the first direction and the second direction.

Some example embodiments of the present disclosure further provide a semiconductor device that includes a substrate; a bit line on the substrate, the bit line extending in a first direction parallel to an upper surface of the substrate; a channel layer on the bit line, the channel layer including a first vertical portion and a second vertical portion, the second vertical portion being spaced apart from the first vertical portion in the first direction; a word line between the first vertical portion and the second vertical portion, the word line extending in a second direction that intersects the first direction; a gate insulating film between the word line and the channel layer; a contact structure above the first vertical portion, the contact structure including a plurality of first grains; a lower electrode extending in a third direction on the contact structure, the third direction being a vertical direction that intersects the first direction and the second direction; and a seed layer between the first vertical portion and the contact structure, the seed layer including a plurality of second grains. Grains from among the plurality of first grains that contact an upper surface of the seed layer have a length in the third direction that is longer than a length of the grains in the second direction, and grains from among the plurality of second grains that contact the first vertical portion are spaced apart from a lower surface of the contact structure in the third direction.

Some example embodiments of the present disclosure still further provide a semiconductor device that includes a substrate; a bit line on the substrate, the bit line extending in a first direction parallel to an upper surface of the substrate; mold patterns extending on the bit line in a second direction that intersects the first direction, the mold patterns being spaced apart from each other in the first direction; a channel layer including a first vertical portion, a second vertical portion and a horizontal portion, the second vertical portion being spaced apart from the first vertical portion in the first direction, the horizontal portion connecting the first vertical portion and the second vertical portion, the horizontal portion extending along an upper surface of the bit line, and the channel layer being between the mold patterns; a word line including a first word line and a second word line, the first word line being on one side of the first vertical portion, the second word line being on one side of the second vertical portion, and the first word line and the second word line extending in the second direction; a gate insulating film between the first word line and the channel layer, and between the second word line and the channel layer; a contact structure above the first vertical portion, the contact structure including a plurality of first grains; a seed layer between the contact structure and the first vertical portion, the seed layer including a plurality of second grains; and a capacitor structure including a lower electrode on the contact structure. At least one of the plurality of first grains contacts an upper surface of the seed layer and a lower surface of the lower electrode, and grains from among the plurality of second grains that contact the channel layer are spaced apart from the contact structure in a third direction, and the third direction is a vertical direction that intersects each of the first direction and the second direction.

According to some example embodiments of the present disclosure, because the contact structure of the semiconductor device is formed of a single grain, resistance may be lowered, and/or electrical characteristics may be improved.

### BRIEF DESCRIPTION OF THE DRAWINGS

The above some example embodiments and features of the present disclosure will become more apparent in view of the following detailed description of some example embodiments with reference to the attached drawings, in which:

FIG. 1 is a plan view for explaining a semiconductor memory device according to some example embodiments of the present disclosure.

FIG. 2 is a cross-sectional view taken along line A-A′ of FIG. 1.

FIG. 3 is an enlarged view showing an R1 region of FIG. 2.

FIG. 4 is an enlarged view showing an R2 region of FIG. 3.

FIG. 5 is a diagram for explaining a semiconductor device according to some example embodiments of the present disclosure.

FIG. 6 is a diagram for explaining a semiconductor device according to some example embodiments of the present disclosure.

FIGS. 7, 8, 9, 10, 11, 12, 13, 14, 15 and 16 are diagrams for explaining a method of manufacturing a semiconductor device according to some example embodiments of the present disclosure.

### DETAILED DESCRIPTION

Hereinafter, a semiconductor device according to some example embodiments of the present disclosure will be described in detail with reference to the drawings.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

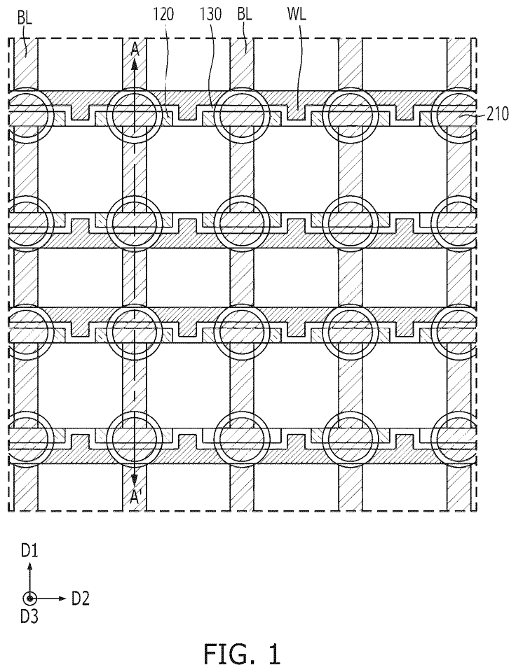

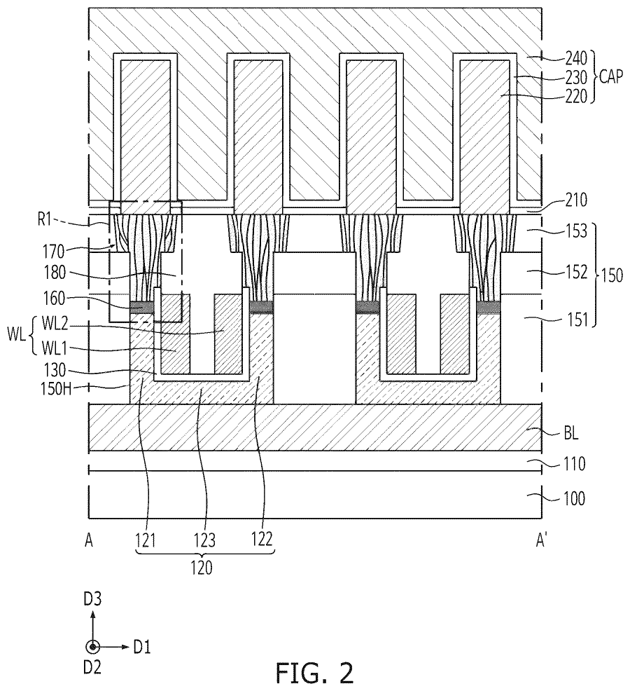

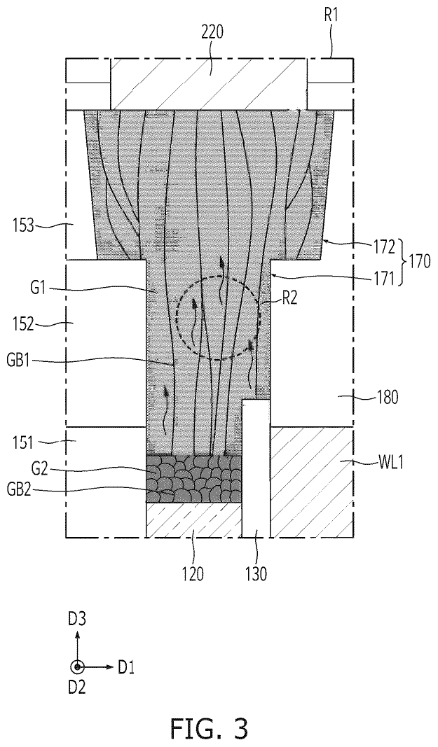

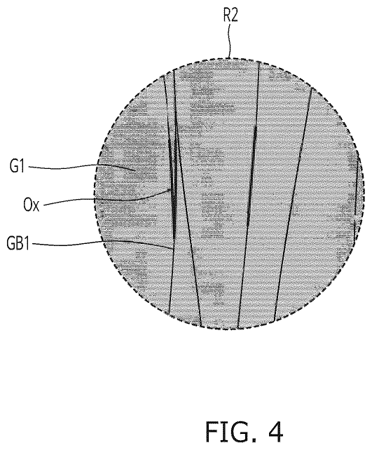

FIG. 1 is a plan view for explaining a semiconductor memory device according to some example embodiments of the present disclosure. FIG. 2 is a cross-sectional view taken along line A-A′ of FIG. 1. FIG. 3 is an enlarged view showing an R1 region of FIG. 2. FIG. 4 is an enlarged view showing an R2 region of FIG. 3. For convenience of explanation, a dielectric film 230 and an upper electrode 240 of a capacitor structure CAP are omitted in FIG. 1.

A semiconductor memory device according to some example embodiments of the present disclosure may include memory cells including vertical channel transistors VCT. The vertical channel transistor VCT may refer to a transistor in which a channel length extends in a direction perpendicular to an upper surface of a semiconductor substrate.

Referring to FIGS. 1 to 4, a semiconductor device according to some example embodiments may include a substrate 100, a wiring insulating film 110, a bit line BL, a channel layer 120, a word line WL, a gate insulating film 130, a mold pattern 150, a seed layer 160, a contact structure 170, a gate separation structure 180, and a capacitor structure CAP.

The substrate 100 may be a semiconductor substrate. The substrate 100 may include, for example, silicon (Si), silicon germanium (SiGe), indium antimonide (InSb), lead telluride compound (PbTe), indium arsenide (InAs), indium phosphide (InP), gallium arsenide (GaAs), or gallium antimonide (GaSb), etc. However, the present disclosure is not limited thereto.

In some example embodiments, a plurality of transistors connected to the bit line BL may be disposed in the substrate 100. For example, a sensing transistor, a transfer transistor, a driving transistor, etc., may be disposed in the substrate 100. The type of transistor may vary depending on the design layout of the semiconductor memory device. A region where a plurality of transistors are disposed in the substrate 100 may be referred to as a peripheral circuit region.

The wiring insulating film 110 may be disposed on the substrate 100. Although not shown, in some example embodiments, a wiring structure may be disposed in the wiring insulating film 110. The wiring structure may electrically connect the substrate 100 and the bit line BL. For example, a plurality of transistors disposed in the substrate 100 may be electrically connected to the bit line BL through the wiring structure.

The bit line BL may be disposed on the wiring insulating film 110. The bit line BL may extend in a first direction D1 on the wiring insulating film 110. Adjacent bit lines BL among a plurality of bit lines BL may be disposed spaced apart from each other in a second direction D2. Here, the second direction D2 may be a direction perpendicular to the first direction D1.

The bit line BL may include a conductive layer and a contact layer. The contact layer may be disposed on the conductive layer. The conductive layer may include, for example, at least one of doped polysilicon, a metal (e.g., Al, Cu, Ti, Ta, Ru, W, Mo, Pt, Ni, Co), a conductive metal nitride (e.g., TiN, TaN, WN, NbN, TiAlN, TiSiN, TaSiN, RuTiN), a conductive metal silicide, or a conductive metal oxide (e.g., PtO, RuO2, IrO2, SRO(SrRuO3), BSRO((Ba, Sr)RuO3), CRO(CaRuO3), LSCo), but the present disclosure is not limited thereto. The contact layer may include, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a two-dimensional (2D) material.

The mold pattern 150 may be disposed on an upper surface of the bit line BL. The mold pattern 150 may extend in the second direction D2. The mold patterns 150 may be spaced apart and aligned in the first direction D1. For example, the mold patterns 150 may be defined as a first mold pattern and a second mold pattern. The first mold pattern may contact a first vertical portion 121 of the channel layer 120, and the second mold pattern may contact a second vertical portion 122 of the channel layer 120.

The mold pattern 150 may include a first insulating layer 151, a second insulating layer 152, and a third insulating layer 153. The first insulating layer 151, the second insulating layer 152, and the third insulating layer 153 may include an insulating material. The first insulating layer 151, the second insulating layer 152, and the third insulating layer 153 may include at least one of silicon oxide, silicon nitride, silicon oxynitride, and a low-k dielectric material. For example, the first insulating layer 151 and the third insulating layer 153 may include silicon oxide, and the second insulating layer 152 may include silicon nitride.

A mold opening 150H may be formed between the mold patterns 150. For example, the mold pattern 150 may define therein a mold opening 150H. The mold opening 150H may expose the upper surface of the bit line BL. The mold opening 150H may be defined by sidewalls of adjacent mold patterns 150 and the upper surface of the bit line BL. The mold opening 150H may be formed between each of the adjacent mold patterns 150.

The channel layer 120 may be disposed in the mold opening 150H. The channel layer 120 may be disposed between adjacent mold patterns 150 in the first direction D1. The channel layer 120 may have a U-shaped vertical cross-section. The channel layer 120 may be disposed on the upper surface of the bit line BL. The channel layer 120 may be connected to the bit line BL. The channel layers 120 disposed on one bit line BL may be spaced apart in the first direction D1.

The channel layer 120 may include a first vertical portion 121, a second vertical portion 122, and a horizontal portion 123.

The first vertical portion 121 and the second vertical portion 122 may be spaced apart in the first direction D1. Each of the first vertical portion 121 and the second vertical portion 122 may extend in a third direction D3. The first vertical portion 121 may be disposed on one surface of the mold opening 150H, and the second vertical portion 122 may be disposed on the other surface of the mold opening 150H. Here, the third direction D3 may be a direction intersecting (e.g., perpendicular to) each of the first direction D1 and the second direction D2. The third direction D3 may be a vertical direction perpendicular to the upper surface of the substrate 100.

The horizontal portion 123 may extend in the first direction D1. The horizontal portion 123 may extend along the upper surface of the bit line BL. The horizontal portion 123 may connect the first vertical portion 121 and the second vertical portion 122. For example, the horizontal portion 123 may connect a lower portion of the first vertical portion 121 and a lower portion of the second vertical portion 122. For example, the first vertical portion 121 may extend in the third direction D3 from one end of the horizontal portion 123, and the second vertical portion 122 may extend in the third direction D3 from the other end of the horizontal portion 123. However, the present disclosure is not limited thereto. Unlike shown in the figures, the horizontal portion 123 may be separated into two parts. For example, a part of the separated horizontal portion 123 may be connected to the first vertical portion 121, and another part of the separated horizontal portion 123 may be connected to the second vertical portion 122. A part of the gate separation structure 180 may be disposed between the separated horizontal portions 123.

The channel layer 120 may include an oxide semiconductor. The oxide semiconductor may include, for example, at least one of InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO, and InxGayO, but the present disclosure is not limited thereto. For example, the channel layer 120 may include IGZO (Indium Gallium Zinc Oxide). The channel layer 120 may include a single layer or multiple layers of the oxide semiconductor. The channel layer 120 may include an amorphous, crystalline, or polycrystalline oxide semiconductor. In some example embodiments, the channel layer 120 may include single-crystal silicon.

In some example embodiments, the channel layer 120 may have a bandgap energy greater than the bandgap energy of silicon. For example, the channel layer 120 may have a bandgap energy of about 1.5 eV to 5.6 eV. For example, the channel layer 120 may have optimal channel performance when the channel layer 120 has a bandgap energy of about 2.0 eV to 4.0 eV. For example, the channel layer 120 may be polycrystalline or amorphous, but the present disclosure is not limited thereto. In some example embodiments, the channel layer 120 may include a two-dimensional semiconductor material. The two-dimensional semiconductor material may include, for example, graphene, a carbon nanotube, or a combination thereof.

The word line WL may be disposed on the channel layer 120. The word line WL may intersect the bit line BL. The word line WL may extend in the second direction D2. The word lines WL may be disposed spaced apart in the first direction D1.

The word line WL may include a first word line WL1 and a second word line WL2. Each of the first word line WL1 and the second word line WL2 may be disposed on the channel layer 120. Each of the first word line WL1 and the second word line WL2 may be disposed between the first vertical portion 121 and the second vertical portion 122. The first word line WL1 and the second word line WL2 may be disposed spaced apart in the first direction D1. For example, the first word line WL1 may be disposed on one side of the horizontal portion 123 and the first vertical portion 121, and the second word line WL2 may be disposed on one side of the horizontal portion 123 and the second vertical portion 122.

An upper surface of the first word line WL1 may be disposed higher than an upper surface of the first vertical portion 121. An upper surface of the second word line WL2 may be disposed higher than an upper surface of the second vertical portion 122.

A width of the first word line WL1 in the first direction D1 may not be constant. For example, a width in the first direction D1 of a portion of the first word line WL1 disposed on the channel layer 120 may be smaller than a width in the first direction D1 of a portion of the first word line WL1 not disposed on the channel layer 120. For example, a width in the first direction D1 of a portion of the first word line WL1 disposed between the channel layers 120 may be smaller than a width in the first direction D1 of a portion of the first word line WL1 not disposed between the channel layers 120. A width of the second word line WL2 in the first direction D1 may also be configured to be the same as, substantially the same as or similar to that of the first word line WL1.

The word line WL may include, for example, at least one of doped polysilicon, a metal (e.g., Al, Cu, Ti, Ta, Ru, W, Mo, Pt, Ni, Co), a conductive metal nitride (e.g., TiN, TaN, WN, NbN, TiAlN, TiSiN, TaSiN, RuTiN), a conductive metal silicide, or a conductive metal oxide (e.g., PtO, RuO2, IrO2, SRO(SrRuO3), BSRO((Ba, Sr)RuO3), CRO(CaRuO3), LSCo), but the present disclosure is not limited thereto. The word line WL may include a single layer of each of the aforementioned materials or a multilayer of the materials. In some example embodiments, the word line WL may include a two-dimensional semiconductor material. The two-dimensional semiconductor material may include, for example, graphene, a carbon nanotube, or a combination thereof.

The gate insulating film 130 may be disposed between the word line WL and the channel layer 120. The gate insulating film 130 may have a U-shaped vertical cross-section. For example, the gate insulating film 130 may be disposed between the first word line WL1 and the first vertical portion 121, and between the second word line WL2 and the second vertical portion 122, respectively. The gate insulating film 130 may extend in the second direction D2 parallel to the first word line WL1 and the second word line WL2. The first word line WL1 and the second word line WL2 may not be in contact with the channel layer 120 due to the gate insulating film 130.

A part of the gate insulating film 130 may protrude in the third direction D3 from (e.g., above) an upper surface of the first word line WL1 and an upper surface of the second word line WL2. For example, a top portion of the gate insulating film 130 may be disposed higher than the upper surface of the first word line WL1 and the upper surface of the second word line WL2.

The gate insulating film 130 may include at least one of silicon oxide, silicon oxynitride, and a high-k dielectric material having a higher dielectric constant than silicon oxide. The high-k dielectric material may include a metal oxide or a metal oxynitride. For example, a high-k dielectric material usable as the gate insulating film 130 may include at least one of HfO2, HfSiO, HfSiON, HfTaO, HfTiO, HfZrO, ZrO2, and Al2O3, but the present disclosure is not limited thereto. For example, the gate insulating film 130 may include Al2O3.

The seed layer 160 may be disposed on the channel layer 120. For example, the seed layer 160 may be disposed on an upper surface of the first vertical portion 121 and/or an upper surface of the second vertical portion 122. An upper surface of the seed layer 160 may be located at a lower vertical level than a top of the gate insulating film 130. The upper surface of the seed layer 160 may be located at a lower vertical level than an upper surface of the word line WL. In some example embodiments, a thickness of the seed layer 160 in the third direction D3 may be variously configured.

The seed layer 160 may be interposed between the channel layer 120 and the contact structure 170. The seed layer 160 may reduce the size of a Schottky Barrier between the channel layer 120 and the contact structure 170. For example, the seed layer 160 may improve electrical performance by reducing the resistance of the contact structure 170.

The seed layer 160 may include at least one of TiN, TiAlC, TiAlN, TiSiN, TiWN, Mo, MoSix, MoSiN, MoN, W, Ta, TaN, LaN, Al, Cu, or Ru. For example, the seed layer 160 may include molybdenum (Mo). The seed layer 160 may be formed through a deposition process such as a physical vapor deposition (PVD), a chemical vapor deposition (CVD) process, or an atomic layer deposition (ALD) process.

The seed layer 160 may have a polycrystalline structure. The seed layer 160 may include a plurality of second grains G2. The second grains G2 may be conformally formed along a side surface of the mold pattern 150, an upper surface of the channel layer 120, and a side surface of the gate insulating film 130. For example, the second grains G2 may be formed to fill a space defined by the side surface of the mold pattern 150, the upper surface of the channel layer 120, and the side surface of the gate insulating film 130. Therefore, among the plurality of second grains G2, the second grains G2 contacting the upper surface of the channel layer 120 may be spaced apart from a lower surface of the contact structure 170 in the third direction D3.

The contact structure 170 may include a plurality of first grains G1 whose boundaries are defined by a first grain boundary GB1. The plurality of first grains G1 may be formed using the seed layer 160 as a seed. The first grains G1 may be grown in a bottom-up manner from an upper surface of the seed layer 160. Because the first grains G1 are grown from the seed layer 160, unlike the second grains G2 that are conformally deposited, the first grains G1 may not be deposited first on a wall surface (e.g., side surfaces of the mold pattern 150 and the gate separation structure 180). At least some of the first grains G1 may extend along a side surface of the contact structure 170. For example, the first grains G1 may not be arranged in the third direction D3 or a vertical direction along the side surface of the contact structure 170. In some example embodiments, some of the first grains G1 may also be grown from previously grown first grains G1. In some example embodiments, the contact structure 170 may be formed of a single grain.

The first grains G1 may extend substantially in the third direction D3 or a vertical direction. The first grains G1 may be arranged along a horizontal direction. Most of the first grains G1 may have a shape in which a length in the vertical direction is longer than a width in the horizontal direction. The first grains G1 may extend from the upper surface of the seed layer 160 in the third direction D3 or the vertical direction. Grains among the first grains G1 that contact the seed layer 160 may have a length extending in the third direction D3 that is longer than a length extending in the second direction D2. In some example embodiments, at least one of the first grains G1 may extend from a lower surface to an upper surface of the contact structure 170. At least one of the plurality of first grains G1 may contact the upper surface of the seed layer 160 and a lower electrode 220 of the capacitor structure CAP. Some of the plurality of first grains G1 may not extend from the lower surface to the upper surface of the contact structure 170.

An aspect ratio of the first grains G1 may be larger than an aspect ratio of the second grains G2. A size of each of the first grains G1 may be relatively larger than a size of each of the second grains G2. A density of the first grains G1 may be relatively smaller than a density of the second grains G2. A first grain boundary GB1 (e.g., first grain boundaries GB1) defining the first grains G1 may have a smaller density than a second grain boundary GB2 (e.g., second grain boundaries GB2) defining the second grains G2. For example, a dispersion of the first grain boundary GB1 may be smaller than a dispersion of the second grain boundary GB2. A seam and/or a void may not be formed inside the contact structure 170.

Meanwhile, oxygen diffusion may occur through the first grain boundary GB1. A metal oxide Ox may be formed along the first grain boundary GB1 due to oxygen diffusion, which may increase the resistance of the contact structure 170. However, because the first grain boundary GB1 has a relatively low density, less metal oxide may be formed.

Because the first grains G1 are grown in a bottom-up manner, the first grain boundary GB1 may extend substantially in the third direction D3 or a vertical direction. Because the first grain boundary GB1 has a relatively constant directionality, oxygen diffusion may occur relatively less in the second direction D2 or a horizontal direction. On the other hand, because the second grains G2 are formed conformally, the second grain boundary GB2 extends in a vertical or horizontal direction, and oxygen diffusion may also occur more easily. For example, because the first grain boundary GB1 extends substantially in the vertical direction, diffusion of oxygen from the mold pattern 150 or the gate separation structure 180 disposed on a side surface of the contact structure 170 may be limited and/or prevented or mitigated. Accordingly, the contact structure 170 may have a relatively lower resistance compared to when the first grains G1 are formed conformally.

The contact structure 170 may be disposed on the seed layer 160 and the gate insulating film 130. One side surface of the contact structure 170 may contact the mold pattern 150, and the other side surface of the contact structure 170 may contact the gate separation structure 180. The contact structure 170 may be electrically connected to the channel layer 120.

The contact structure 170 may include a first portion 171 and a second portion 172. The first portion 171 may be disposed on the seed layer 160. The first portion 171 may protrude from the second portion 172 toward the bit line BL in the third direction D3. The first portion 171 may contact the seed layer 160 and the gate insulating film 130. A part of the first portion 171 may overlap with each of the first word line WL1 or the second word line WL2 in the first direction D1.

The second portion 172 may be disposed on the first portion 171. A side surface of the second portion 172 may have a step with a side surface of the first portion 171. For example, a width of the second portion 172 in the first direction D1 may be larger than a width of the first portion 171 in the first direction D1. For example, the contact structure 170 may include a step portion between the first portion 171 and the second portion 172.

The side surface of the second portion 172 may be inclined in a direction that narrows toward the first portion 171. A width of the second portion 172 in the second direction D2 may decrease toward the first portion 171. From a planar perspective, the second portion 172 may have various shapes such as a circle, an ellipse, a rectangle, a square, a rhombus, or a hexagon. From a planar perspective, the second portion 172 may be arranged in various forms such as a matrix form, a zigzag form, or a honeycomb form along the first direction D1 and the second direction D2. An upper surface of the second portion 172 may be located coplanar with an upper surface of the mold pattern 150.

The contact structure 170 may include a metal capable of selective growth. For example, the contact structure 170 may include one of molybdenum (Mo), tungsten (W), cobalt (Co), ruthenium (Ru), silver (Ag), gold (Au), rhenium (Re), iridium (Ir), rhodium (Rh), palladium (Pd), osmium (Os), niobium (Nb), nickel (Ni), zinc (Zn), vanadium (V), or aluminum (Al), but is not limited thereto.

The gate separation structure 180 may be disposed in the mold opening 150H. The gate separation structure 180 may be disposed on the word line WL and the gate insulating film 130. The gate separation structure 180 may be spaced apart from the bit line BL in the third direction D3. In some example embodiments, the gate separation structure 180 may contact the channel layer 120. For example, the gate separation structure 180 may penetrate the gate insulating film 130.

The gate separation structure 180 may separate the first word line WL1 and the second word line WL2 in the first direction D1. The gate separation structure 180 may be disposed between the first word line WL1 and the second word line WL2. The gate separation structure 180 may extend in the second direction D2 between the first word line WL1 and the second word line WL2.

The gate separation structure 180 may include an insulating material. For example, the gate separation structure 180 may include silicon oxide, silicon nitride, etc. In some example embodiments, the gate separation structure 180 may have a multi-layer structure.

An upper surface of the gate separation structure 180 may be located coplanar with an upper surface of the mold pattern 150. For example, a distance from an upper surface of the bit line BL to the upper surface of the gate separation structure 180 may be the same or substantially the same as a distance from the upper surface of the bit line BL to the upper surface of the mold pattern 150.

An etch stop film 210 may be disposed on the contact structure 170 and the mold pattern 150. For example, the etch stop film 210 may include silicon nitride, silicon oxynitride, or a combination thereof. The etch stop film 210 may limit and/or prevent an etchant from flowing under a lower electrode 220 during a wet etching process, thereby limiting and/or preventing the mold pattern 150 from being etched.

The capacitor structure CAP may be disposed on the etch stop film 210, the gate separation structure 180, and the contact structure 170. The capacitor structure CAP may store a signal transmitted from a transistor in a peripheral circuit structure (e.g., a row and column decoder, a sense amplifier, etc.) of the semiconductor device. The capacitor structure CAP may be used as an information storage element electrically connected to a transistor. For example, the capacitor structure CAP may store charge by the control of a transistor.

The capacitor structure CAP may include a lower electrode 220, a dielectric film 230, and an upper electrode 240.

The lower electrode 220 may be disposed on the contact structure 170. The lower electrode 220 may extend in the third direction D3. The lower electrode 220 may be electrically connected to the contact structure 170. A part of the lower electrode 220 may be disposed in the etch stop film 210. For example, the lower electrode 220 may penetrate the etch stop film 210 to be connected to the contact structure 170.

The lower electrode 220 may include, for example, at least one of a conductive metal material (cobalt (Co), titanium (Ti), nickel (Ni), tungsten (W), molybdenum (Mo), etc.), a metal nitride (titanium nitride (TiN), titanium silicon nitride (TiSiN), titanium aluminum nitride (TiAlN), tantalum aluminum nitride (TaAlN), tungsten nitride (WN), etc.), a noble metal material (platinum (Pt), ruthenium (Ru), iridium (Ir), etc.), a conductive oxide film (PtO, RuO2, IrO2, SRO(SrRuO3), BSRO((Ba, Sr)RuO3), CRO(CaRuO3), LSCo, etc.), and a metal silicide film. However, the present disclosure is not limited thereto. In some example embodiments, at least one supporter may be disposed between the lower electrodes 220. The supporter may support the lower electrode 220.

The dielectric film 230 may be disposed on the lower electrode 220 and the etch stop film 210. The dielectric film 230 may cover the lower electrode 220. The dielectric film 230 may extend along a profile of the lower electrode 220. The dielectric film 230 may include, for example, silicon oxide, silicon nitride, silicon oxynitride, and a high-k material including a metal. Although the dielectric film 230 is shown as a single film, this is for convenience of explanation only, and the present disclosure is not limited thereto. Unlike what is shown, the dielectric film 230 may include a plurality of films.

The upper electrode 240 may be disposed on the dielectric film 230. The upper electrode 240 may cover the dielectric film 230. The lower electrode 220, the dielectric film 230, and the upper electrode 240 may be sequentially disposed. The upper electrode 240 may fill an empty space between the lower electrodes 220. The upper electrode 240 may include, for example, at least one of an elemental semiconductor material film or a compound semiconductor material film. The upper electrode 240 may include doped n-type impurities or p-type impurities.

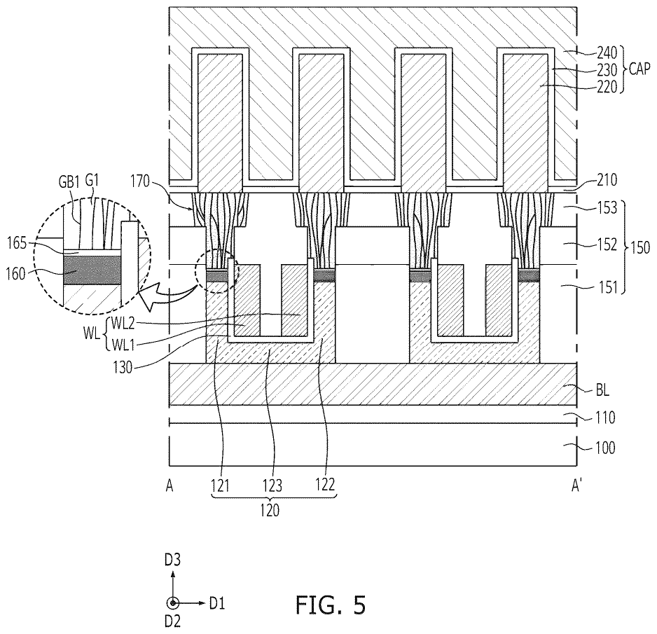

FIG. 5 is a diagram for explaining a semiconductor device according to some example embodiments of the present disclosure. For convenience of explanation, detailed description of the same configurations as the embodiment of FIGS. 1 to 4 will be omitted, and the description will focus on different configurations.

Referring to FIG. 5, a semiconductor device according to some example embodiments of the present disclosure may further include an oxide layer 165 compared to the embodiment of FIGS. 1 to 4.

The oxide layer 165 may be interposed between the seed layer 160 and the contact structure 170. The oxide layer 165 may be formed by oxidizing a material constituting the seed layer 160. For example, the oxide layer 165 may include molybdenum oxide (MoOx). The oxide layer 165 may be formed while the seed layer 160 is exposed to the air after the formation of the seed layer 160. For example, the oxide layer 165 may be formed after the seed layer 160 is formed and before the contact structure 170 is formed.

An upper surface of the oxide layer 165 may contact a lower surface of the contact structure 170. A first grain boundary GB1 that divides a plurality of first grains G1 may contact the upper surface of the oxide layer 165. Oxygen may diffuse from the oxide layer 165 through the first grain boundary GB1.

The oxide layer 165 may be disposed between the mold pattern 150 and the gate insulating film 130. In some example embodiments, the oxide layer 165 may be located at a higher vertical level than a top of the gate insulating film 130.

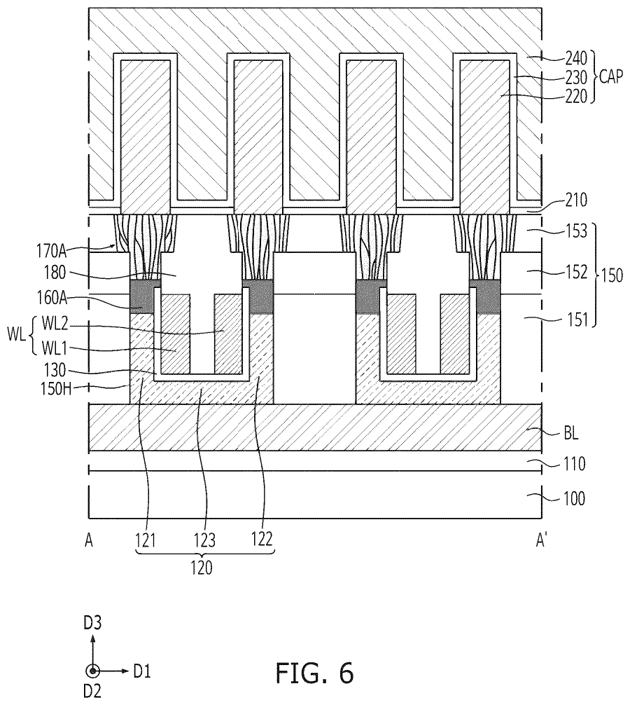

FIG. 6 is a diagram for explaining a semiconductor device according to some example embodiments of the present disclosure. For convenience of explanation, detailed description of the same configurations as the embodiment of FIGS. 1 to 4 will be omitted, and the description will focus on different configurations.

Referring to FIG. 6, in a semiconductor device according to some example embodiments of the present disclosure, the structures of a seed layer 160A and a contact structure 170A may be different from those of the embodiment of FIGS. 1 to 4.

The seed layer 160A may be disposed on the channel layer 120. The seed layer 160A may be disposed on an upper surface of the first vertical portion 121 and/or an upper surface of the second vertical portion 122. An upper surface of the seed layer 160A may be located at a higher vertical level than a top of the gate insulating film 130. The upper surface of the seed layer 160A may be located at a higher vertical level than an upper surface of the word line WL. For example, a thickness of the seed layer 160A in the third direction D3 may be greater than a thickness of the seed layer 160 of FIG. 2 in the third direction D3. In some example embodiments, the upper surface of the seed layer 160A may be located at a higher vertical level than the upper surface of the word line WL and at a lower vertical level than the top of the gate insulating film 130.

A lower surface of the contact structure 170A may be located at a higher vertical level than the upper surface of the word line WL. A thickness of the contact structure 170A in the third direction D3 may be smaller than a thickness of the contact structure 170 of FIG. 2 in the third direction D3. As such, the thickness of the seed layer 160A in the third direction D3 and the thickness of the contact structure 170A in the third direction D3 may be appropriately adjusted.

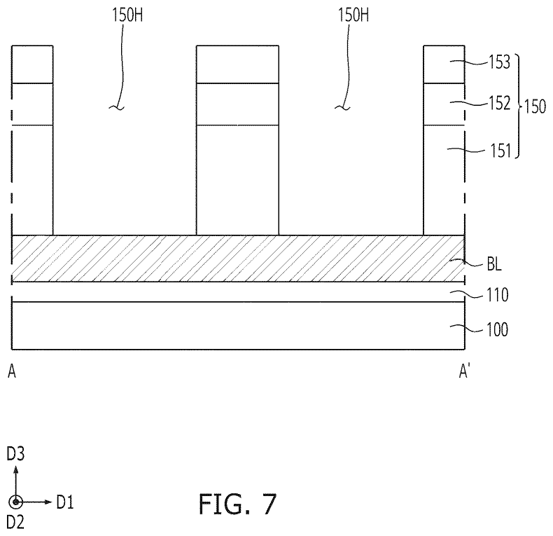

FIGS. 7 to 16 are diagrams for explaining a method of manufacturing a semiconductor device according to some example embodiments of the present disclosure.

Referring to FIG. 7, a wiring insulating film 110, a bit line BL, and a preliminary mold pattern may be formed on a substrate 100.

The substrate 100 may be a semiconductor substrate. The substrate 100 may include, for example, silicon (Si), silicon germanium (SiGe), indium antimonide (InSb), lead telluride compound (PbTe), indium arsenide (InAs), indium phosphide (InP), gallium arsenide (GaAs), or gallium antimonide (GaSb), etc. However, the present disclosure is not limited thereto.

Although not shown, in some example embodiments, a plurality of transistors connected to the bit line BL may be disposed in the substrate 100. For example, a sensing transistor, a transfer transistor, a driving transistor, etc., may be disposed in the substrate 100. The type of transistor may vary depending on the design layout of the semiconductor memory device. A region where a plurality of transistors are disposed in the substrate 100 may be referred to as a peripheral circuit region.

The wiring insulating film 110 may be formed on the substrate 100. A bit line BL and a bit line insulating film may be formed on the wiring insulating film 110. The bit line BL may extend in a first direction D1 on the wiring insulating film 110. Adjacent bit lines BL may be disposed spaced apart from each other in a second direction D2. A bit line insulating film may be disposed between adjacent bit lines BL.

A preliminary mold pattern may be formed on an upper surface of the bit line BL and an upper surface of the bit line insulating film. The preliminary mold pattern may be formed by sequentially stacking a first insulating film 151, a second insulating film 152, and a third insulating film 153. The preliminary mold pattern may cover the bit line BL.

Subsequently, a part of the preliminary mold pattern may be removed to form a mold pattern 150. For example, a part of the preliminary mold pattern may be removed through an etching process. A hard mask pattern may be formed on the preliminary mold pattern. The hard mask pattern may expose a part of the preliminary mold pattern. A mold opening 150H may be formed by removing a part of the preliminary mold pattern exposed by the hard mask pattern. The mold opening 150H may expose the upper surface of the bit line BL.

The remaining part of the preliminary mold pattern 150p that is not removed may become the mold pattern 150. The mold pattern 150 may extend in the second direction D2. The mold patterns 150 may be disposed spaced apart in the first direction D1.

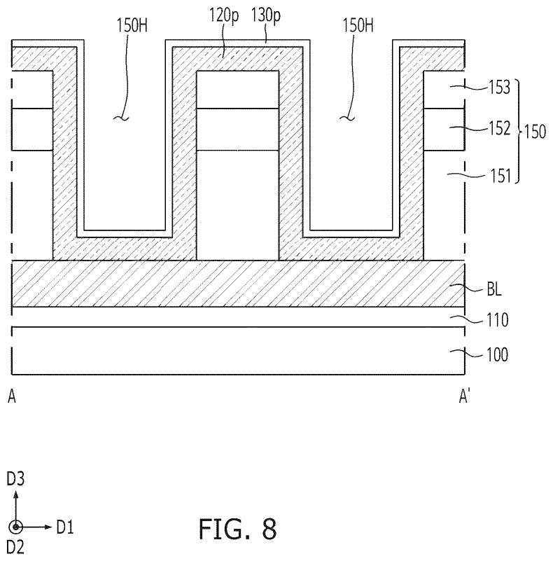

Referring to FIG. 8, a preliminary channel layer 120p and a preliminary gate insulating film 130p may be formed.

The preliminary channel layer 120p and the preliminary gate insulating film 130p may be sequentially formed on an upper surface of the mold pattern 150 and in the mold opening 150H. The preliminary channel layer 120p and the preliminary gate insulating film 130p may be conformally formed on the upper surface of the mold pattern 150 and in the mold opening 150H. For example, the preliminary channel layer 120p and the preliminary gate insulating film 130p may be formed using at least one of a chemical vapor deposition (CVD), a low-pressure CVD, a plasma-enhanced CVD, an MOCVD, or an atomic layer deposition (ALD) process.

The preliminary channel layer 120p and the preliminary gate insulating film 130p may extend along a side surface and an upper surface of the mold pattern 150. The preliminary channel layer 120p and the preliminary gate insulating film 130p may have a U-shaped vertical cross-section in the mold opening 150H.

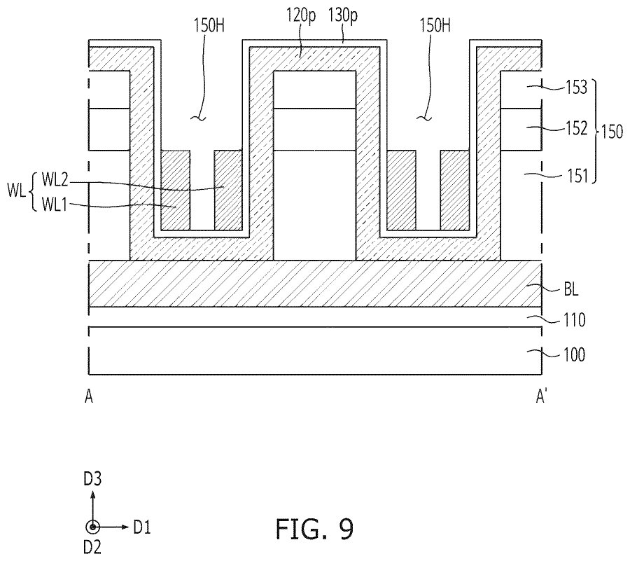

Referring to FIG. 9, a word line WL may be formed in the mold opening 150H. The word line WL may be formed on the preliminary gate insulating film 130p. The word line WL may be formed by removing a part of a preliminary word line layer conformally formed on the preliminary gate insulating film 130p. For example, a part of the preliminary word line layer extending in the first direction D1 in the mold opening 150H may be removed. As a result, the preliminary word line layer may be separated into two parts spaced apart in the first direction D1.

The first word line WL1 and the second word line WL2 may be spaced apart in the first direction D1. The first word line WL1 may be disposed on one side of a first vertical portion 121 with the gate insulating film 130 interposed therebetween, and the second word line WL2 may be disposed on one side of a second vertical portion 122 with the gate insulating film 130 interposed therebetween.

A part of the preliminary word line layer extending in a third direction D3 in the mold opening 150H may be removed. As a result, upper surfaces of the first word line WL1 and the second word line WL2 may be located at a lower vertical level than a top of the preliminary channel layer 120p.

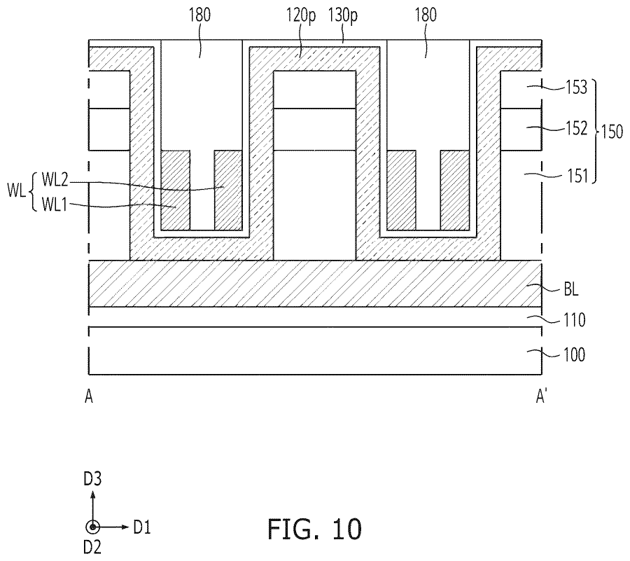

Referring to FIG. 10, a gate separation structure 180 may be formed in the mold opening 130H. A part of the gate separation structure 180 may be disposed between the first word line WL1 and the second word line WL2. In some example embodiments, an etch-back process or a planarization process may be performed on the gate separation structure 180.

In some example embodiments, the preliminary channel layer 120p and the preliminary gate insulating film 130p may be separated into two parts. For example, a part of the gate separation structure 180 may penetrate the preliminary channel layer 120p and the preliminary gate insulating film 130p to contact an upper surface of the bit line BL.

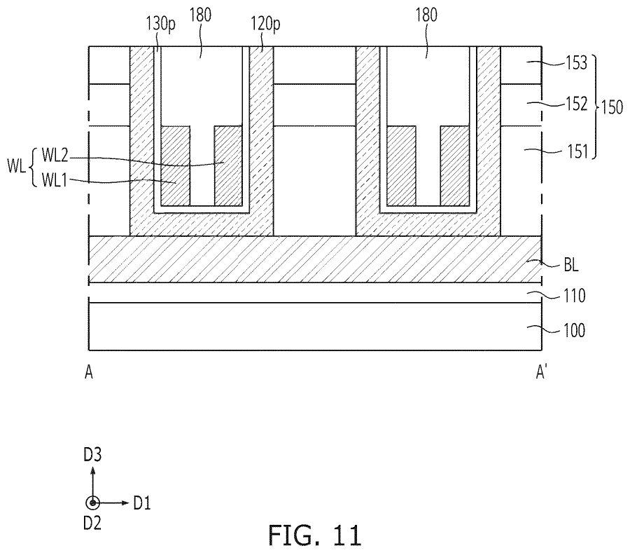

Referring to FIG. 11, an upper part of the preliminary channel layer 120p, the preliminary gate insulating film 130p, and the gate separation structure 180 may be removed. For example, a part of the preliminary channel layer 120p and the preliminary gate insulating film 130p may be removed by an etch-back process or a planarization process.

As such, by the etch-back process or the planarization process, an upper end of the preliminary channel layer 120p and an upper end of the preliminary gate insulating film 130p may be coplanar with an upper surface of the mold pattern 150., as a part of the preliminary channel layer 120p disposed on the upper surface of the mold pattern 150 is removed, the upper surface of the mold pattern 150 may be exposed.

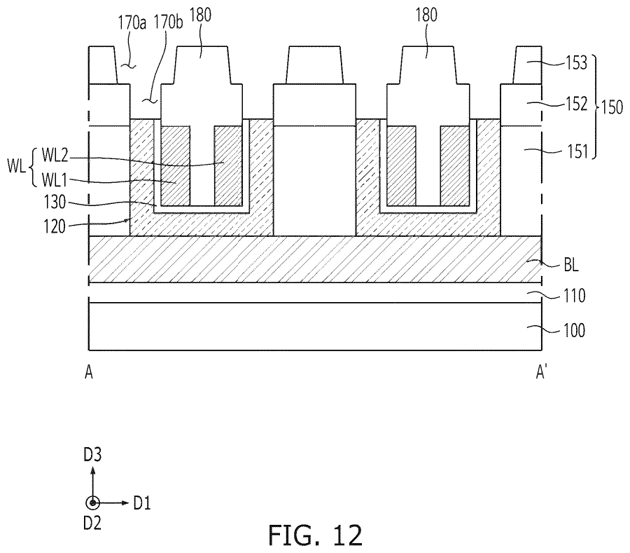

Referring to FIG. 12, a first contact hole 170a and a second contact hole 170b may be formed to expose the channel layer 120 and the gate insulating film 130. For example, the first contact hole 170a may be formed by removing a portion of each of the preliminary channel layer 120p and the preliminary gate insulating film 130p, the mold pattern 150, and the gate separation structure 180.

The second contact hole 170b may be formed by removing a part of the preliminary channel layer 120p and the preliminary gate insulating film 130p through the first contact hole 170a. As a part of the preliminary channel layer 120p and the preliminary gate insulating film 130p is removed, the channel layer 120 and the gate insulating film 130 may be formed. For example, the first contact hole 170a and the second contact hole 170b may be formed by a dry etching process.

A top of the gate insulating film 130 may be located at a higher vertical level than an upper surface of the word line WL. An upper surface of the channel layer 120 may be located at the same vertical level as the top of the gate insulating film 130. As such, the upper surface of the channel layer 120 and the top of the gate insulating film 130 may be exposed.

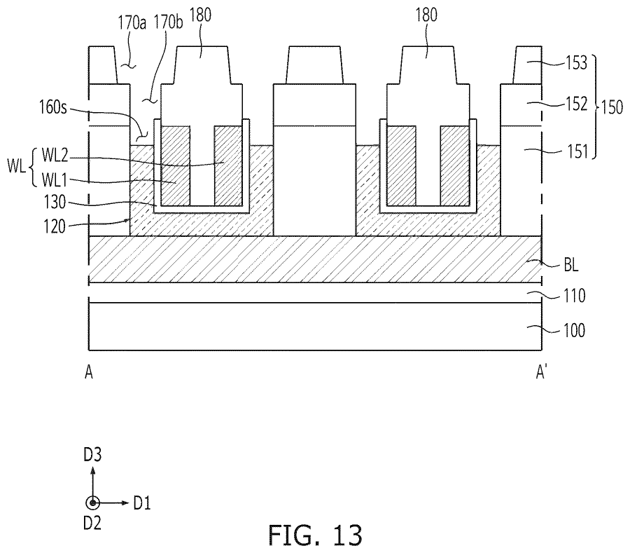

Referring to FIG. 13, an upper part of the channel layer 120 may be removed. For example, the upper part of the channel layer 120 may be removed by a wet etching process. The wet etching process may have an etch selectivity with respect to the gate insulating film 130. As a result, the upper surface of the channel layer 120 may be disposed at a lower vertical level than a top of the word line WL.

A seed region 160s defined by the upper surface of the channel layer 120, a side surface of the mold pattern 150, and a side surface of the gate insulating film 130 may be formed. The seed region 160s may be formed to have a desired (and/or alternatively predetermined) thickness in a third direction D3 from the upper surface of the channel layer 120. In some example embodiments, the seed region 160s may be defined to have a larger thickness.

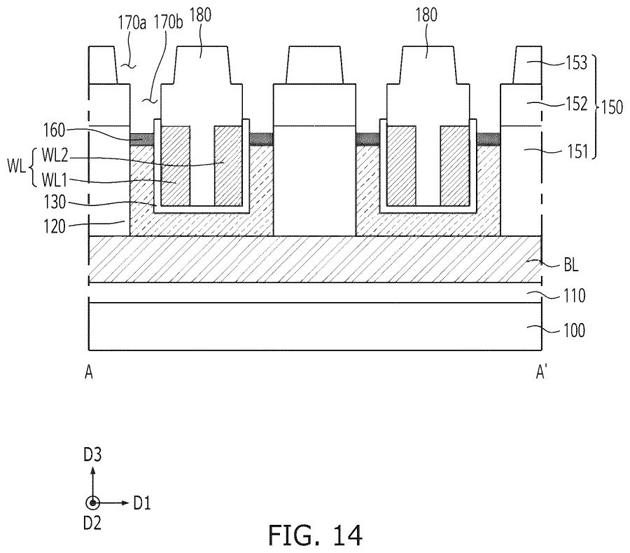

Referring to FIG. 14, a seed layer 160 may be formed on an upper surface of the channel layer 120.

The seed layer 160 may be formed through a deposition process such as PVD, CVD, or ALD. The seed layer 160 may be conformally deposited in a seed region defined by the upper surface of the channel layer 120, a side surface of the mold pattern 150, and a side surface of the gate insulating film 130. The seed layer 160 may be formed by introducing a deposition gas through a first contact hole 170a and a second contact hole 170b. For example, second grains constituting the seed layer 160 may be formed first on the upper surface of the channel layer 120, the side surface of the mold pattern 150, and the side surface of the gate insulating film 130, and gradually fill the seed region.

Subsequently, a step of removing a part deposited outside the seed region by a planarization process or an etch-back process may be additionally performed. As a result, the seed layer 160 may be formed to have a uniform thickness.

The seed layer 160 may include, for example, at least one of TiN, TiAlC, TiAlN, TiSiN, TiWN, Mo, MoSix, MoSiN, MoN, W, Ta, TaN, LaN, Al, Cu, or Ru. For example, the seed layer 160 may include molybdenum (Mo).

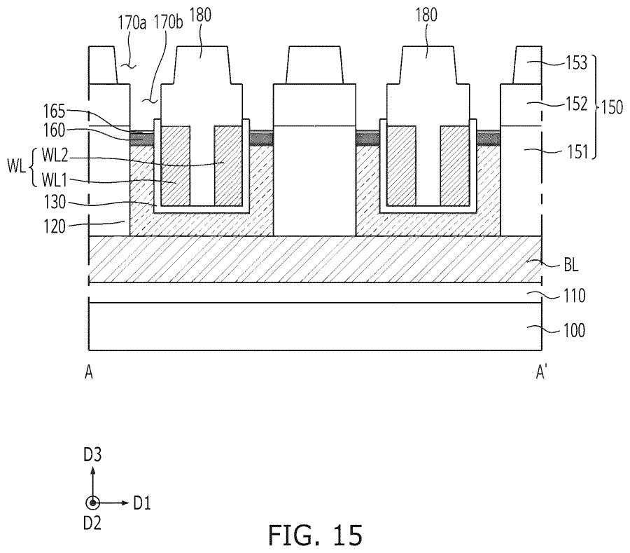

Referring to FIG. 15, an oxide layer 165 may be formed on the seed layer 160. While the seed layer 160 is exposed to the air, a part of the material constituting the seed layer 160 may be oxidized to form the oxide layer 165.

The oxide layer 165 may be formed on an upper surface of the seed layer 160. For example, the oxide layer 165 may include molybdenum oxide (MoOx). However, the present disclosure is not limited thereto, and a material constituting the oxide layer 165 may vary depending on a material constituting the seed layer 160.

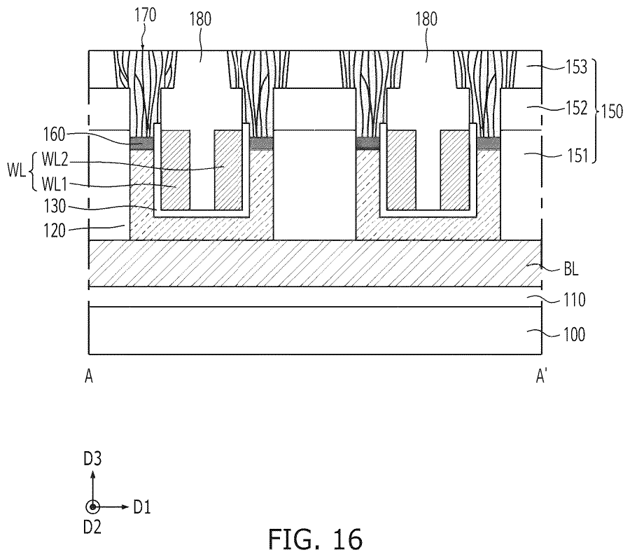

Referring to FIG. 16, a contact structure 170 may be formed on the seed layer 160. For example, a second portion of the contact structure 170 may be formed in a first contact hole 170a, and a first portion of the contact structure 170 may be formed in a second contact hole 170b. In some example embodiments, the oxide layer 165 may be removed before forming the contact structure 170. For example, the oxide layer 165 may be removed by a cleaning process.

The contact structure 170 may be deposited from the seed layer 160 by a selective growth method. For example, the contact structure 170 may be formed by a CVD or ALD process. For example, in a deposition process for forming the contact structure 170, a difference in deposition reaction may exist between a surface of a metal layer (e.g., the seed layer 160) and a surface of an insulating layer (e.g., the mold pattern 150 and the gate separation structure 180). For example, a deposition reaction may occur relatively better on the surface of the metal layer than on the surface of the insulating layer.

As such, first grains constituting the contact structure 170 may be grown in a bottom-up manner using the seed layer 160 as a seed. The first grains may be grown in a vertical direction from an upper surface of the seed layer 160. Unlike being conformally deposited, the first grains may extend in a third direction D3 or a vertical direction from the seed layer 160. In some example embodiments, at least one of the first grains may extend from the upper surface of the seed layer 160 to an upper surface of the contact structure 170. Alternatively, at least some of the first grains may extend along a side surface of the contact structure 170.

According to some other example embodiments of the present disclosure, a method for manufacturing a semiconductor device includes sequentially forming a wiring insulating film and a bit line extending in a first direction on a substrate, forming a mold opening and a mold pattern on the bit line, forming a channel layer and a gate insulating film in the mold opening, forming a first word line extending in a second direction intersecting the first direction on one side of the channel layer, forming a seed layer on an upper surface of the channel layer, and forming a contact structure on the seed layer, and the contact structure may be grown from the seed layer and include a plurality of first grains having a length in a third direction intersecting each of the first direction and the second direction that is longer than a length in the second direction.

According to some example embodiments of the present disclosure, the plurality of first grains may be formed by a selective growth method from the seed layer.

According to some example embodiments of the present disclosure, the method may further include forming a lower electrode on the contact structure, and at least one of the plurality of first grains may contact an upper surface of the seed layer and a lower surface of the lower electrode.

According to some example embodiments of the present disclosure, the method may further include, before forming the contact structure on the seed layer, performing a cleaning process on the seed layer to remove an oxide layer.

According to some example embodiments of the present disclosure, the seed layer may include at least one of TiN, TiAlC, TiAlN, TiSiN, TiWN, Mo, MoSix, MoSiN, MoN, W, Ta, TaN, LaN, Al, Cu, or Ru, and the contact structure may include at least one of Ti, Mo, or W.

According to some example embodiments of the present disclosure, the contact structure may include a first portion contacting the seed layer and a second portion on the first portion contacting the lower electrode, and a side surface of the second portion and a side surface of the first portion may have a step.

According to some example embodiments of the present disclosure, the seed layer may include a plurality of second grains conformally formed by a deposition process.

Some example embodiments of the present disclosure further provide a method of manufacturing a semiconductor device that includes forming a bit line on a substrate, the bit line extending in a first direction; forming a channel layer on the bit line, the channel layer including a first vertical portion; forming a first word line on one side of the first vertical portion, the first word line extending in a second direction that intersects the first direction; forming a gate insulating film between the first word line and the channel layer; forming a seed layer on the channel layer; forming a contact structure on the seed layer, the contact structure including a plurality of first grains; and forming an electrode on the contact structure. Grains from among the plurality of first grains that contact an upper surface of the seed layer are formed as a having a length in a third direction that is longer than a length of the grains in the second direction, and the third direction is a vertical direction that intersects each of the first direction and the second direction.

In some example embodiments of the method of manufacturing the semiconductor device, the forming the seed layer includes forming the upper surface of the seed layer at a lower vertical level or at a same vertical level as a top of the gate insulating film.

In some example embodiments, the method of manufacturing the semiconductor device further includes forming an oxide layer between the seed layer and the contact structure.

In some example embodiments of the method of manufacturing the semiconductor device, the forming the seed layer includes forming a part of the seed layer overlapping the gate insulating film in the third direction.

In some example embodiments of the method of manufacturing the semiconductor device, the seed layer includes a plurality of second grains, and grains from among the plurality of second grains that contact the channel layer are formed spaced apart from the contact structure.

In some example embodiments of the method of manufacturing the semiconductor device, at least one of the plurality of first grains are formed contacting the upper surface of the seed layer and a lower surface of the lower electrode.

In some example embodiments of the method of manufacturing the semiconductor device, the contact structure is formed as having a plurality of first grain boundaries dividing the plurality of first grains, and a metal oxide along at least part of the plurality of first grain boundaries.

In some example embodiments of the method of manufacturing the semiconductor device, at least one of the plurality of first grains is formed extending along a side surface of the contact structure.

In some example embodiments of the method of manufacturing the semiconductor device, the forming the channel layer includes forming a second vertical portion spaced apart from the first vertical portion in the first direction; and forming a horizontal portion connecting the first vertical portion and the second vertical portion, the horizontal portion extending along an upper surface of the bit line.

In some example embodiments, the method of manufacturing the semiconductor device further includes forming a second word line on one side of the second vertical portion; and forming a gate separation structure between the first word line and the second word line.

In some example embodiments of the method of manufacturing the semiconductor device, the forming the contact structure includes forming a first portion contacting the seed layer; forming a second portion on the first portion, the second portion contacting the lower electrode; and forming a step portion between a side surface of the second portion and a side surface of the first portion.

Although some example embodiments of the present inventive concepts have been described with reference to drawings, the present inventive concepts are not limited thereto, and various modifications and variations are possible by those of ordinary skill in the art to which the present inventive concepts pertains within the scope of the technical idea of the present inventive concepts and the equivalent scope of the claims to be described below.

What is claimed is:

1. A semiconductor device, comprising:
a substrate;
a bit line on the substrate, the bit line extending in a first direction parallel to an upper surface of the substrate;
a channel layer including a first vertical portion on the bit line;
a first word line on one side of the first vertical portion, the first word line extending in a second direction that intersects the first direction;
a gate insulating film between the first word line and the channel layer;
a seed layer on the channel layer;
a contact structure on the seed layer, the contact structure comprising a plurality of first grains; and
a capacitor structure comprising a lower electrode on the contact structure,
wherein grains from among the plurality of first grains that contact an upper surface of the seed layer have a length in a third direction that is longer than a length of the grains in the second direction, and the third direction is a vertical direction that intersects each of the first direction and the second direction.

2. The semiconductor device of claim 1, wherein the upper surface of the seed layer is at a lower vertical level or a same vertical level as a top of the gate insulating film.

3. The semiconductor device of claim 1, further comprising an oxide layer between the seed layer and the contact structure.

4. The semiconductor device of claim 1, wherein a part of the seed layer overlaps the gate insulating film in the third direction.

5. The semiconductor device of claim 1, wherein the seed layer comprises a plurality of second grains, and
grains from among the plurality of second grains contact the channel layer and are spaced apart from the contact structure.

6. The semiconductor device of claim 1, wherein at least one of the plurality of first grains contacts the upper surface of the seed layer and a lower surface of the lower electrode.

7. The semiconductor device of claim 1, wherein the contact structure has
a plurality of first grain boundaries dividing the plurality of first grains, and
a metal oxide along at least part of the plurality of first grain boundaries.

8. The semiconductor device of claim 1, wherein at least one of the plurality of first grains extends along a side surface of the contact structure.

9. The semiconductor device of claim 1, wherein the channel layer further comprises:
a second vertical portion spaced apart from the first vertical portion in the first direction; and
a horizontal portion connecting the first vertical portion and the second vertical portion, the horizontal portion extending along an upper surface of the bit line.

10. The semiconductor device of claim 9, further comprising:
a second word line on one side of the second vertical portion; and
a gate separation structure between the first word line and the second word line.

11. The semiconductor device of claim 1, wherein the contact structure comprises:
a first portion contacting the seed layer;
a second portion on the first portion, the second portion contacting the lower electrode; and
a step portion between a side surface of the second portion and a side surface of the first portion.

12. The semiconductor device of claim 1, wherein the seed layer comprises at least one of TiN, TiAlC, TiAlN, TiSiN, TiWN, Mo, MoSix, MoSiN, MoN, W, Ta, TaN, LaN, Al, Cu, or Ru.

13. The semiconductor device of claim 1, wherein the contact structure comprises at least one of Ti, Mo, or W.

14. The semiconductor device of claim 1, wherein the channel layer comprises IGZO.

15. A semiconductor device, comprising:
a substrate;
a bit line on the substrate, the bit line extending in a first direction parallel to an upper surface of the substrate;
a channel layer on the bit line, the channel layer including a first vertical portion and a second vertical portion, the second vertical portion being spaced apart from the first vertical portion in the first direction;
a word line between the first vertical portion and the second vertical portion, the word line extending in a second direction that intersects the first direction;
a gate insulating film between the word line and the channel layer;
a contact structure above the first vertical portion, the contact structure comprising a plurality of first grains;
a lower electrode extending in a third direction on the contact structure, the third direction being a vertical direction that intersects the first direction and the second direction; and
a seed layer between the first vertical portion and the contact structure, the seed layer comprising a plurality of second grains,
wherein grains from among the plurality of first grains that contact an upper surface of the seed layer have a length in the third direction that is longer than a length of the grains in the second direction, and
grains from among the plurality of second grains that contact the first vertical portion are spaced apart from a lower surface of the contact structure in the third direction.

16. The semiconductor device of claim 15, wherein the contact structure has
a plurality of first grain boundaries dividing the plurality of first grains, and
a metal oxide along at least part of the plurality of first grain boundaries.

17. The semiconductor device of claim 15, wherein
the contact structure has a plurality of first grain boundaries dividing the plurality of first grains,
the seed layer has a plurality of second grain boundaries dividing the plurality of second grains, and
a density of the plurality of first grain boundaries is smaller than a density of the plurality of second grain boundaries.

18. The semiconductor device of claim 15, further comprising:
a mold pattern on a side surface of the channel layer, on a side surface of the contact structure, and on the bit line, the mold pattern extending in the second direction,
wherein the mold pattern comprises a first insulating film on an upper surface of the bit line, a second insulating film on the first insulating film, and a third insulating film on the second insulating film, and a side surface of the first insulating film and a side surface of the second insulating film are coplanar, and
the mold pattern includes a step between the side surface of the second insulating film and a side surface of the third insulating film.

19. The semiconductor device of claim 18, wherein the first insulating film and the third insulating film comprise silicon oxide, and the second insulating film comprises silicon nitride.

20. A semiconductor device, comprising:
a substrate;
a bit line on the substrate, the bit line extending in a first direction parallel to an upper surface of the substrate;
mold patterns extending on the bit line in a second direction that intersects the first direction, the mold patterns being spaced apart from each other in the first direction;
a channel layer comprising a first vertical portion, a second vertical portion and a horizontal portion, the second vertical portion being spaced apart from the first vertical portion in the first direction, the horizontal portion connecting the first vertical portion and the second vertical portion, the horizontal portion extending along an upper surface of the bit line, and the channel layer being between the mold patterns;
a word line comprising a first word line and a second word line, the first word line being on one side of the first vertical portion, the second word line being on one side of the second vertical portion, and the first word line and the second word line extending in the second direction;
a gate insulating film between the first word line and the channel layer, and between the second word line and the channel layer;
a contact structure above the first vertical portion, the contact structure comprising a plurality of first grains;
a seed layer between the contact structure and the first vertical portion, the seed layer comprising a plurality of second grains; and
a capacitor structure comprising a lower electrode on the contact structure,
wherein at least one of the plurality of first grains contacts an upper surface of the seed layer and a lower surface of the lower electrode, and
grains from among the plurality of second grains that contact the channel layer are spaced apart from the contact structure in a third direction, and the third direction is a vertical direction that intersects each of the first direction and the second direction.
